(19) United States
(12) Patent Application Publication
(10) Pub. No.: US 2025/0212334 A1
(43) Pub. Date: Jun. 26, 2025

(54) SEMICONDUCTOR MODULE

(71) Applicant: Mitsubishi Electric Corporation, Tokyo (JP)

(72) Inventors: Taketoshi SHIKANO, Tokyo (JP); Yosuke NAKATA, Tokyo (JP)

(73) Assignee: Mitsubishi Electric Corporation, Tokyo (JP)

(21) Appl. No.: 18/903,544

(22) Filed: Oct. 1, 2024

(30) Foreign Application Priority Data
Dec. 21, 2023 (JP) 2023-215886

(51) Int. Cl. H05K 1/18; H01L 23/498; H01L 25/10; H05K 1/11

(52) U.S. Cl. CPC H05K 1/181; H01L 23/49811; H01L 25/105; H05K 1/113; H05K 2201/09481; H05K 2201/10545

(57) ABSTRACT

A molded package in which a semiconductor chip is sealed with transfer molding resin, and a package assembly attached to a package terminal projecting from a package side surface of the molded package are included. The package assembly includes a printed circuit board that is physically and electrically connected to the package terminal, and an external terminal mounted on the printed circuit board and electrically connected to the package terminal.

### BACKGROUND OF THE INVENTION

### Field of the Invention

The present disclosure relates to a semiconductor module, and more particularly to a semiconductor module in which an external terminal can be freely laid out.

### Description of the Background Art

Due to high reliability and high heat resistance, as a technique for sealing a power semiconductor chip, a technique of a molded package using thermosetting resin such as epoxy resin generally used in manufacture of an integrated circuit (IC) or the like is used.

As a general manufacturing process, a circuit pattern or the like is formed on a plate material made from metal such as copper (Cu) or a Cu alloy, a circuit element is connected to the circuit pattern, a lead frame punched out by press working or the like is then sandwiched between mold dies constituted by upper and lower dies, transfer molding resin is injected into a cavity in the mold die, and heating and application of pressure are performed for curing reaction so that a package is formed.

For this reason, an external terminal connected to a higher system such as a control system has a prismatic shape, and is formed by projecting from a side surface of a package and being bent upward or downward. For this reason, with a molded package, it has been difficult to cope with a mounting method of press-fitting into a through hole of a printed circuit board PCB or the like, such as a system using a press-fit terminal and the like widely employed in a general-purpose case-type power module as disclosed in FIG. 8(a) in Kota Ohara et al., CIB Type Of Industrial Seventh Generation IGBT, Mitsubishi Denki giho, 92. No. 3, 183 to 186 (2018).

In a conventional molded package, which is molded with a mold die, an external terminal structurally projects from a side surface of a package, and has a prismatic terminal shape, which is bent upward or downward. For this reason, there has been a problem that it is not possible to freely lay out an external terminal or employ a special terminal shape such as press-fit.

### SUMMARY

An object of the present disclosure is to provide a semiconductor module in which an external terminal can be freely laid out while a molded package is used, and a special terminal shape can also be employed.

A semiconductor module according to the present disclosure includes a molded package in which a semiconductor chip is sealed with transfer molding resin, and a package assembly attached to a package terminal projecting from a package side surface of the molded package. The package assembly includes a printed circuit board that is physically and electrically connected to the package terminal, and an external terminal mounted on the printed circuit board and electrically connected to the package terminal.

According to the semiconductor module of the present disclosure, it is possible to obtain a semiconductor module in which an external terminal can be freely laid out while a molded package is used, and a special terminal shape can also be employed.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a side view illustrating a configuration of a general molded package;

FIG. 2 is a side view illustrating a configuration of a semiconductor module of a first preferred embodiment according to the present disclosure;

FIG. 3 is a side view illustrating another configuration of the semiconductor module of the first preferred embodiment according to the present disclosure;

FIG. 4 is a side view illustrating a configuration of the semiconductor module of a second preferred embodiment according to the present disclosure;

FIG. 5 is a perspective view illustrating a configuration of the semiconductor module of a variation of the second preferred embodiment according to the present disclosure;

FIG. 6 is a side view illustrating a configuration of the semiconductor module of a variation of the second preferred embodiment according to the present disclosure;

FIG. 7 is a side view illustrating a configuration of the semiconductor module of a third preferred embodiment according to the present disclosure;

FIGS. 8 and 9 are side views each illustrating another configuration of the semiconductor module of the third preferred embodiment according to the present disclosure;

FIG. 10 is a perspective view illustrating a PCB used in the semiconductor module of the third preferred embodiment according to the present disclosure;

FIG. 11 is a side view illustrating a use example of a PCB used in the semiconductor module of the third preferred embodiment according to the present disclosure;

FIG. 12 is a side view illustrating a configuration of the semiconductor module of a fourth preferred embodiment according to the present disclosure;

FIG. 13 is a side view illustrating a configuration of the semiconductor module of a fifth preferred embodiment according to the present disclosure;

FIG. 14 is a side view illustrating a configuration of the semiconductor module of a sixth preferred embodiment according to the present disclosure;

FIG. 15 is a side view illustrating another configuration of the semiconductor module of the sixth preferred embodiment according to the present disclosure;

FIG. 16 is a side view illustrating a configuration of the semiconductor module of a seventh preferred embodiment according to the present disclosure;

FIG. 17 is a side view illustrating another configuration of the semiconductor module of an eighth preferred embodiment according to the present disclosure;

FIG. 18 is a perspective view illustrating an example of a semiconductor package used in the semiconductor module of the eighth preferred embodiment according to the present disclosure;

FIG. 19 is a perspective view illustrating a configuration of the semiconductor module of the eighth preferred embodiment according to the present disclosure; and

FIG. 20 is a side view illustrating a configuration of the semiconductor module of a variation of the eighth preferred embodiment according to the present disclosure.

### DESCRIPTION OF THE PREFERRED EMBODIMENTS

### Introduction

In description below, the drawings are schematically illustrated, and a mutual relationship between sizes and positions of images illustrated in different drawings is not necessarily accurately described, and can be appropriately changed. Further, in description below, similar constituent elements are illustrated with the same reference numerals. This similarly applies to their names and functions. Therefore, there is a case where detailed description of them is omitted.

Further, in description below, terms meaning specific positions and directions such as “upper”, “lower”, “side”, “front”, or “back” may be used, but these terms are used for convenience to facilitate understanding of content of a preferred embodiment, and are not related to directions in actual implementation.

### First Preferred Embodiment

FIG. 1 is a side view illustrating a configuration of a semiconductor package 1 that is a general molded package, in which a package terminal 2 projects from a side surface of the package and is bent upward.

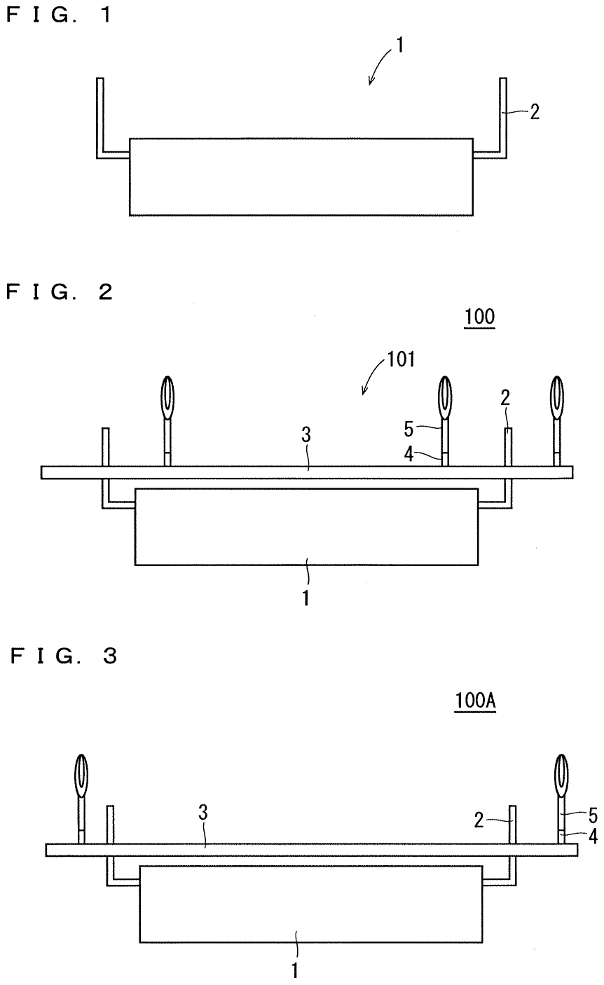

FIG. 2 is a side view illustrating a configuration of a semiconductor module 100 of a first preferred embodiment according to the present disclosure. As illustrated in FIG. 2, in the semiconductor module 100, a package assembly 101 is attached to the semiconductor package 1. The package assembly 101 includes a PCB 3 attached to a package terminal 2 of the semiconductor package 1, a plurality of terminal blocks 4 mounted on the PCB 3, and a press-fit terminal 5 as an external terminal connected to each of the terminal blocks 4.

In the package assembly 101, the package terminal 2 of the semiconductor package 1 is inserted into a through hole (not illustrated) of the PCB 3, and is physically and electrically connected to a circuit pattern (not illustrated) provided on a surface of the PCB 3. Each of the terminal blocks 4 is equipped with a plurality of the press-fit terminals 5 as external terminals, and a plurality of the press-fit terminals 5 are electrically connected to the circuit pattern. As described above, even the package terminal 2 projecting from a side surface of the semiconductor package 1 can be electrically connected to a press-fit terminal effectively and inexpensively. For this reason, even in a case where a system higher than the semiconductor module 100 supports a press-fit terminal, the semiconductor module 100 can be connected.

Further, a terminal that can be mounted on the PCB 3 is not limited to a press-fit terminal, and terminals such as a cylindrical terminal, a spring terminal, and a terminal like a connector can be supported. For this reason, even in a case where a system higher than the semiconductor module 100 supports a terminal other than a press-fit terminal, the semiconductor module 100 can be connected.

Further, in the PCB 3 illustrated in FIG. 2, the terminal block 4 is provided further on the inner side than a position where the package terminal 2 is inserted and projects, and a plurality of the press-fit terminals 5 can be freely laid out without being affected by an arrangement position of the package terminal 2.

Further, in the PCB 3 of a semiconductor module 100A illustrated in FIG. 3, the terminal block 4 is provided further on the outer side than a position where the package terminal 2 is inserted and projects. For this reason, even in a case where the semiconductor package 1 is small, degree of freedom is increased by utilizing the package assembly 101, and a layout of a circuit pattern becomes easy by providing a margin in an inter-terminal distance, so that it is possible to support an industrial field that has been restricted by a higher system. For this reason, the semiconductor modules 100 and 100A can also be used in an industrial facility that has used a general-purpose case type power module as disclosed in FIG. 8(a) of Kota Ohara et al., CIB Type Of Industrial Seventh Generation IGBT, Mitsubishi Denki giho, 92. No. 3, 183 to 186 (2018).

Further, since it is not necessary to design a terminal position of the semiconductor package 1 in accordance with a higher system and to enlarge the semiconductor package 1, material cost of the semiconductor package 1 can be reduced, and productivity can be increased.

### Second Preferred Embodiment

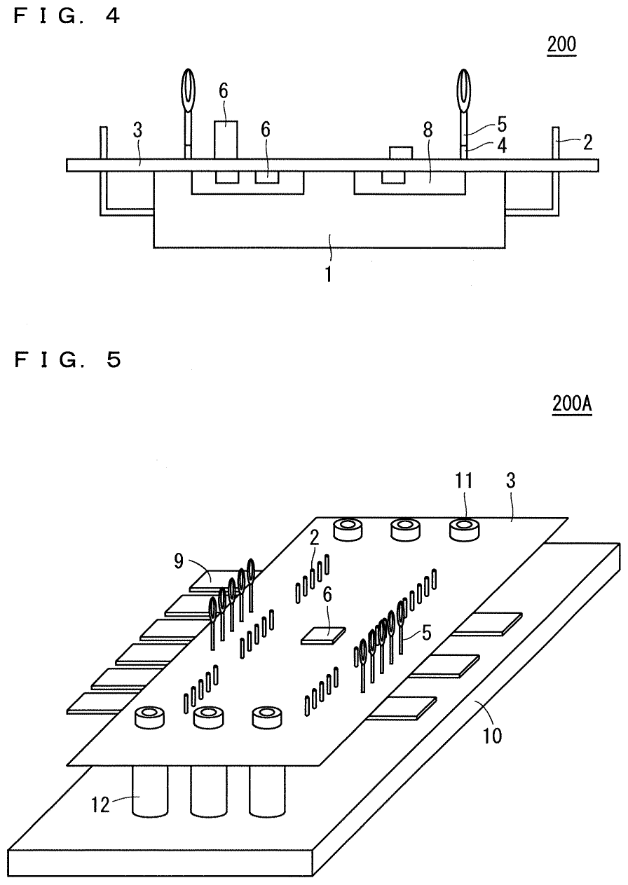

FIG. 4 is a side view illustrating a configuration of a semiconductor module 200 of a second preferred embodiment according to the present disclosure. As illustrated in FIG. 4, in the semiconductor module 200, a package assembly 201 is attached to the semiconductor package 1. The package assembly 201 is functionally enhanced by mounting an electronic component 6 such as a capacitor or a resistor on the PCB 3, and is attached to the package terminal 2 and fixed to the semiconductor package 1 with an adhesive 7 or the like.

For this reason, rigidity of the PCB 3 can be increased, deformation due to heat and external stress can be reduced, insertion and removal characteristics required for the press-fit terminal 5 can be improved, and reliability of the electronic component 6 to be mounted can be improved.

Further, in the semiconductor package 1, a recessed portion 8 is provided on an upper surface facing the PCB 3. The PCB 3 is a both surface mounting board on which the electronic components 6 are mounted on an upper surface and a lower surface, and a package main body is configured to be able to accommodate the electronic component 6 on the lower surface in the recessed portion 8 in a case where the PCB 3 is mounted.

For this reason, in a case where the semiconductor package 1 is small, the electronic components 6 can be efficiently laid out by using the both surface mounting PCB 3, and the entirety including the package assembly 201 and the like can be made smaller than that in a case of using the single surface mounting PCB 3. Further, since a circuit formation using the PCB 3 is enabled, components of an existing product can be aggregated, and the product can be more effectively downsized.

### <Variation>

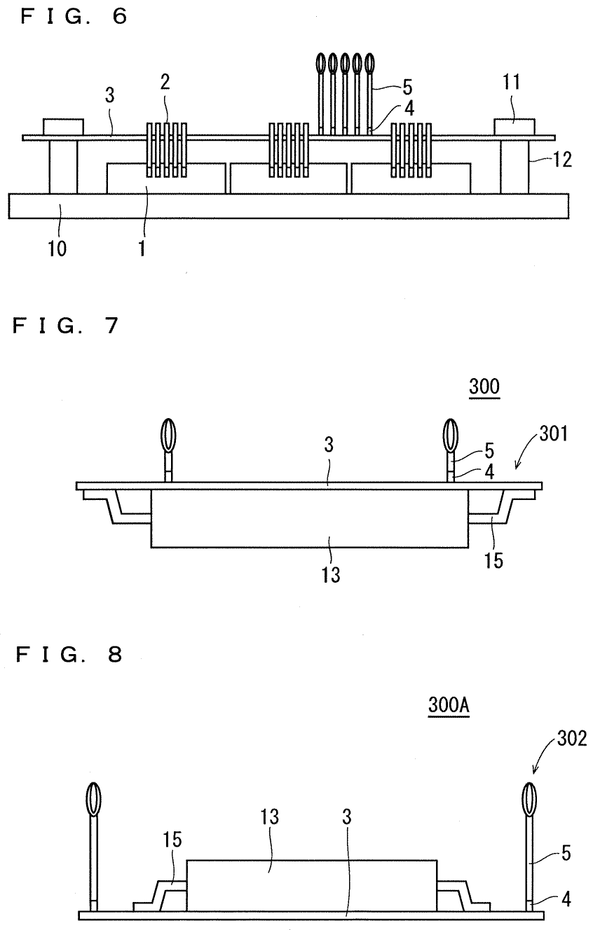

FIG. 5 is a perspective view illustrating a configuration of a semiconductor module 200A of a variation of the second preferred embodiment according to the present disclosure, and FIG. 6 is a side view as viewed from a long side of the semiconductor module 200A. As illustrated in FIGS. 5 and 6, the semiconductor module 200A is the same as the semiconductor module 200 in that the electronic components 6 such as a capacitor and a resistor are mounted on the PCB 3, but rigidity of the PCB 3 is increased by mounting a plurality of the semiconductor packages 1 on a base plate 10 and connecting the base plate 10 and the PCB 3 via a plurality of fixing bases 12 provided on the base plate 10.

The fixing base 12 and the PCB 3 are coupled by a fixing screw 11 passing through the PCB 3. Each of the package terminals 2 of the semiconductor package 1 is inserted into a through hole (not illustrated) of the PCB 3, is physically and electrically connected to a circuit pattern (not illustrated) provided on a surface of the PCB 3, and has a tip projecting from a surface of the PCB 3. Note that, in FIG. 5, a plurality of terminal plates 9 are also provided, but are omitted from description.

By mounting a plurality of the semiconductor packages 1 on the base plate 10 and connecting them via the PCB 3, a terminal position of each of the semiconductor packages 1 is not affected by mounting accuracy of each of the semiconductor packages 1, and common signals can be connected in the PCB 3 to aggregate the terminal plates 9.

Note that, although FIGS. 5 and 6 illustrate a configuration in which a plurality of the semiconductor packages 1 are mounted on the base plate 10, it is also possible to employ a configuration in which the semiconductor package 1 is not mounted on the base plate 10 and only each of the package terminals 2 is mounted on the PCB 3.

### Third Preferred Embodiment

FIG. 7 is a side view illustrating a configuration of a semiconductor module 300 of a third preferred embodiment according to the present disclosure. As illustrated in FIG. 7, in the semiconductor module 300, a package assembly 301 is attached to a surface mount semiconductor package 13. In the package assembly 301, a mounting terminal 15 of the semiconductor package 13 is physically and electrically connected to a circuit pattern (not illustrated) on a lower surface of the PCB 3 of a lower surface mounting type by soldering or the like. Other configurations of the PCB 3 are the same as those of the PCB 3 illustrated in FIG. 1.

Note that although FIG. 7 illustrates the PCB 3 of a lower surface mounting type, the PCB 3 of an upper surface mounting type can also be used. FIG. 8 is a side view illustrating a configuration of a semiconductor module 300A. As illustrated in FIG. 8, in the semiconductor module 300A, the surface mount semiconductor package 13 is mounted on a package assembly 302. In the package assembly 302, the mounting terminal 15 of the semiconductor package 13 is physically and electrically connected to a circuit pattern (not illustrated) on an upper surface of the PCB 3 of an upper surface mounting type by soldering or the like.

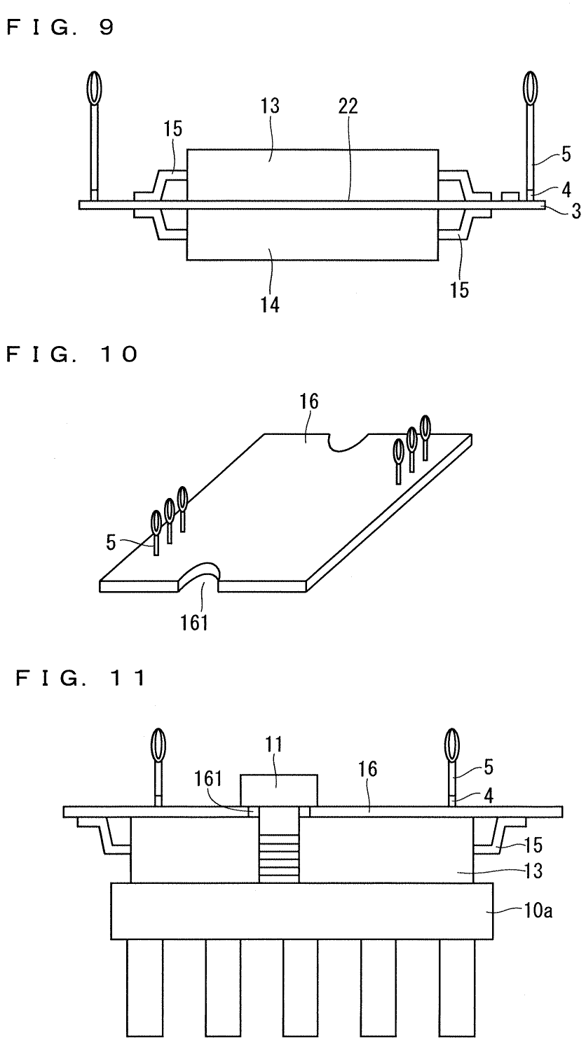

Further, as illustrated in FIG. 9, the PCB 3 of a double surface mounting type can also be used, and the surface mount semiconductor packages 13 and 14 can be attached to an upper surface and a lower surface of the PCB 3 of a double surface mounting type, respectively. The semiconductor package 14 is, for example, a reverse bent semiconductor package. By mounting the semiconductor packages 13 and 14, a parallel circuit can be formed, and power capacity of a semiconductor device can be increased with a small space.

Further, the PCB 3 substrate can have its shaped deformed according to a product, and when a semiconductor package 1A is small, the PCB 3 substrate provided with U-shaped notches on two facing sides of the PCB 3 substrate can be used.

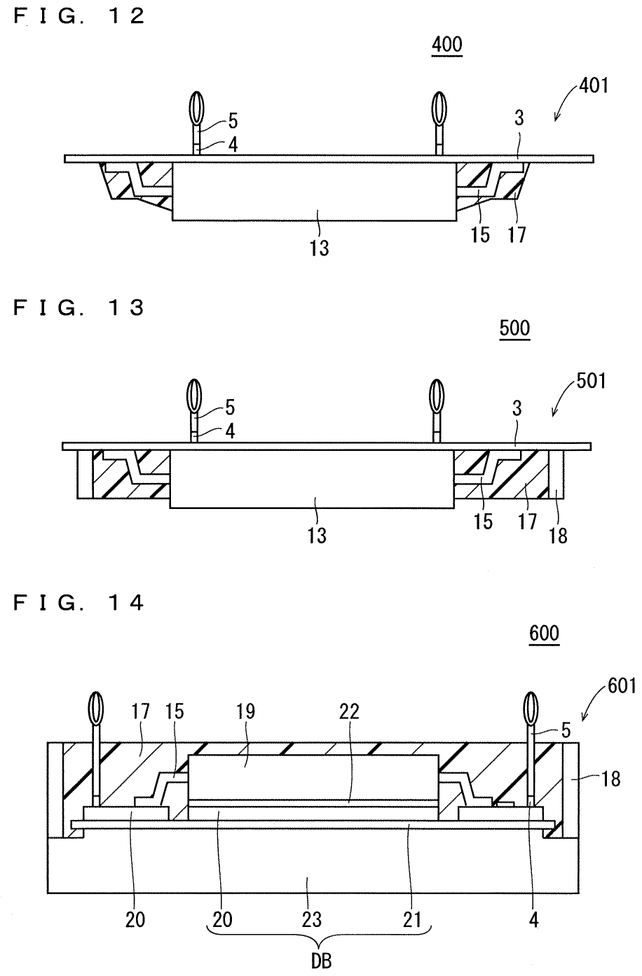

FIG. 10 is a perspective view illustrating a PCB 16 in which U-shaped notches 161 are provided on two facing sides, and FIG. 11 is a side view illustrating a state in which the PCB 16, on which the semiconductor package 13 is mounted on a lower surface, is mounted on a heat sink 10a, and the heat sink 10a and the PCB 16 are coupled by the fixing screw 11. The fixing screw 11 couples the heat sink 10a and the PCB 16 via the notch 161 of the PCB 16. By coupling them by the fixing screw 11, the semiconductor package 13 and the heat sink 10a can be efficiently coupled.

### Fourth Preferred Embodiment

FIG. 12 is a side view illustrating a configuration of a semiconductor module 400 according to a fourth preferred embodiment of the present disclosure. As illustrated in FIG. 12, in the semiconductor module 400, a package assembly 401 is attached to the surface mount semiconductor package 13. In the package assembly 401, the mounting terminal 15 of the semiconductor package 13 is physically and electrically connected to a circuit pattern (not illustrated) on a lower surface of the PCB 3 of a lower surface mounting type by soldering or the like, and a terminal portion is sealed with resin 17 such as a direct potting (DP) resin or an underfill material.

The direct potting resin is resin used for resin-sealing a power semiconductor chip, and for example, epoxy resin can be used.

The underfill material is epoxy resin containing a fine filler having low viscosity and a particle diameter of about several μm, penetrates into a narrow gap by a capillary phenomenon, and contributes to insulation property and fixation between components by being cured.

As described above, by sealing the terminal portion with the DP resin or the underfill material, it is possible to secure creepage between terminals of the semiconductor package 13 and secure space insulation. Further, it is possible to prevent adhesion of dust or the like to a terminal and improve reliability.

### Fifth Preferred Embodiment

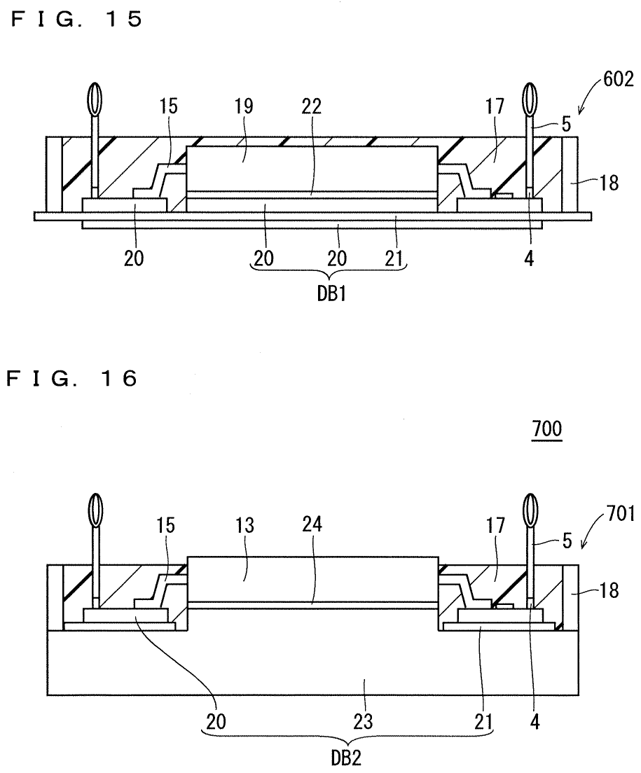

FIG. 13 is a side view illustrating a configuration of a semiconductor module 500 of a fifth preferred embodiment according to the present disclosure. As illustrated in FIG. 13, in the semiconductor module 500, a package assembly 501 is attached to the surface mount semiconductor package 13. In the package assembly 501, the mounting terminal 15 of the semiconductor package 13 is physically and electrically connected to a circuit pattern (not illustrated) on a lower surface of the PCB 3 of a lower surface mounting type by soldering or the like, and a guide 18 having a case shape is provided so as to accommodate the semiconductor package 13. The resin 17 such as DP resin or an underfill material is sealed inside the guide 18, and the semiconductor package 13 including a terminal portion is resin-sealed.

By the above, even in a case where a creepage distance cannot be secured by downsizing of the package, insulation between terminals can be guaranteed by the resin 17.

That is, in a molded package, since voltage close to withstand voltage is applied between main electrodes, it is necessary to take a creepage distance between terminals and to a substrate to be mounted, but creepage can be eliminated by covering with DP resin or the like. For this reason, even in a case where a molded package is downsized as a whole and a distance between terminals is reduced to such an extent that a creepage distance cannot be secured by a semiconductor package alone, insulation between terminals can be maintained by covering with DP resin or the like.

### Sixth Preferred Embodiment

FIG. 14 is a side view illustrating a configuration of a semiconductor module 600 of a sixth preferred embodiment according to the present disclosure. As illustrated in FIG. 14, in the semiconductor module 600, a package assembly 601 is attached to a surface mount non-insulating semiconductor package 19.

The non-insulating semiconductor package 19 is, for example, a package in which a conductor member such as a die pad or a heat sink on which a semiconductor chip is mounted is directly exposed on a back surface of the package, and a conductor member such as Cu is exposed on the back surface, and can be bonded to a substrate with a solder material for electrical conduction, silver (Ag), Cu sinter, or the like.

In FIG. 14, a back surface of the non-insulating semiconductor package 19 is bonded to a Cu pattern 20 provided on an upper surface of a direct bonded copper (DBC) substrate DB functioning as an insulating substrate via a bonding material 22 such as a solder material, Ag, or Cu sinter. The DBC substrate DB includes a ceramic substrate 21 functioning as an insulating layer, the Cu pattern 20 provided on an upper surface of the ceramic substrate 21, and a heat spreader 23 on which the ceramic substrate 21 is mounted. The Cu pattern 20 is electrically separated into a portion to which the non-insulating semiconductor package 19 is bonded and a portion to which the mounting terminal 15 is physically and electrically connected by soldering or the like.

In the package assembly 601, a conductor member (not illustrated) exposed on a back surface of the non-insulating semiconductor package 19 is physically and electrically connected to the Cu pattern 20 on an upper surface of the DBC substrate DB by soldering or the like, and the guide 18 having a case shape is provided to accommodate the non-insulating semiconductor package 19. The resin 17 such as DP resin or an underfill material is sealed inside the guide 18, and the non-insulating semiconductor package 19 including a terminal portion is resin-sealed.

By the above, even in a case where a creepage distance cannot be secured by downsizing of the package, insulation between terminals can be guaranteed by the resin 17.

As a package assembly applied to the non-insulating semiconductor package 19, a package assembly 602 as illustrated in FIG. 15 can also be employed. In FIG. 15, a back surface of the non-insulating semiconductor package 19 is bonded to the Cu pattern 20 provided on an upper surface of a DBC substrate DB1 via a bonding material 22. The DBC substrate DB1 includes the ceramic substrate 21 and the Cu patterns 20 provided on an upper surface and a lower surface of the ceramic substrate 21. The Cu pattern 20 on an upper surface is electrically separated into a portion to which the non-insulating semiconductor package 19 is bonded and a portion to which the mounting terminal 15 is physically and electrically connected by soldering or the like.

In the package assembly 602, a conductor member (not illustrated) exposed on a back surface of the non-insulating semiconductor package 19 is physically and electrically connected to the Cu pattern 20 on an upper surface of the DBC substrate DB1 by soldering or the like, and the guide 18 having a case shape is provided to accommodate the non-insulating semiconductor package 19. The resin 17 is sealed inside the guide 18, and the non-insulating semiconductor package 19 including a terminal portion is resin-sealed.

### Seventh Preferred Embodiment

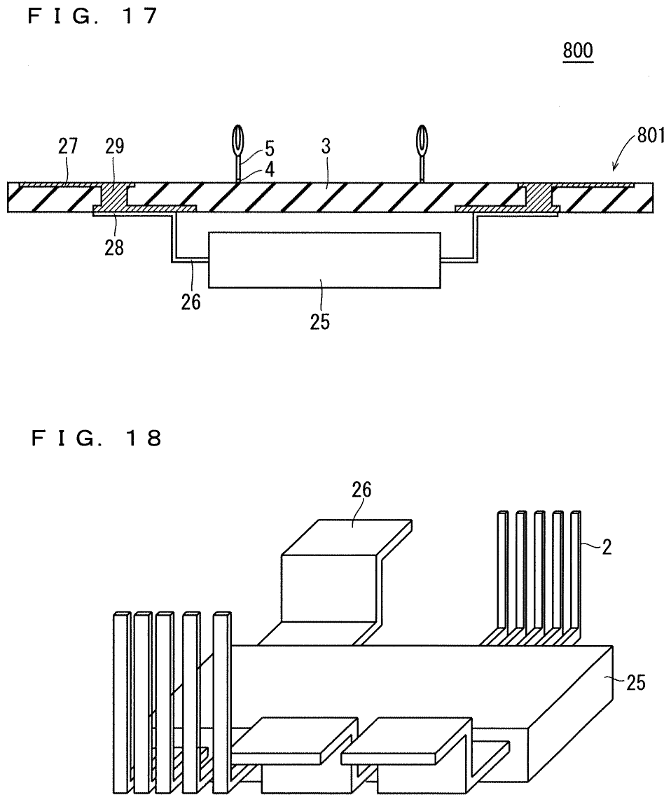

FIG. 16 is a side view illustrating a configuration of a semiconductor module 700 of a seventh preferred embodiment according to the present disclosure. As illustrated in FIG. 16, in the semiconductor module 700, a package assembly 701 is attached to the surface mount semiconductor package 13. In the package assembly 701, a back surface of the semiconductor package 13 is bonded to an upper surface of the heat spreader 23 of a DBC substrate DB2 via a heat dissipation bonding material 24 such as high heat dissipation adhesive resin or an adhesive sheet, and the guide 18 having a case shape is provided so as to accommodate the semiconductor package 13. The resin 17 such as DP resin or an underfill material is sealed inside the guide 18, and the non-insulating semiconductor package 19 including a terminal portion is resin-sealed.

By the above, even in a case where a creepage distance cannot be secured by downsizing of the package, insulation between terminals can be guaranteed by the resin 17.

The DBC substrate DB2 includes the ceramic substrate 21 functioning as an insulating layer, the Cu pattern 20 provided on an upper surface of the ceramic substrate 21, and the heat spreader 23. The ceramic substrate 21 is provided at a position corresponding to a lower portion of the Cu pattern 20 to which the mounting terminal 15 is physically and electrically connected by soldering or the like.

### Eighth Preferred Embodiment

FIG. 17 is a side view illustrating a configuration of a semiconductor module 800 of an eighth preferred embodiment according to the present disclosure. As illustrated in FIG. 17, in the semiconductor module 800, a main current terminal 26 of a semiconductor package 25 for large current is attached to the PCB 3. Note that the package terminal 2 of the semiconductor package 25 is also attached to the PCB 3, but is not illustrated.

A package assembly 801 includes the PCB 3, a plurality of the terminal blocks 4 mounted on the PCB 3, the press-fit terminal 5 connected to each of the terminal blocks 4, an upper surface main terminal electrode 27 provided on an upper surface of the PCB 3, a lower surface main terminal electrode 28 provided on a lower surface of the PCB 3, and an in-substrate wiring 29. The upper surface main terminal electrode 27 and the lower surface main terminal electrode 28 are electrically connected to each other via the in-substrate wiring 29.

The main current terminal 26 projecting from a side surface of the semiconductor package 25 is physically and electrically connected to the lower surface main terminal electrode 28 by soldering or the like.

FIG. 18 is a perspective view illustrating a configuration example of the semiconductor package 25. As illustrated in FIG. 18, the main current terminal 26 and the package terminal 2 project from a facing side surface of the semiconductor package 25, and are bent so as to be parallel to a side surface of the package. The main current terminal 26 is further bent in a direction perpendicular to a side surface of the package.

FIG. 19 is a perspective view illustrating a configuration of the semiconductor module 800. As illustrated in FIG. 19, in the semiconductor module 800, the electronic components 6 such as a capacitor and a resistor are mounted on the PCB 3, a plurality of the semiconductor packages 25 (not illustrated) are mounted on the base plate 10, and the base plate 10 and the PCB 3 are connected via a plurality of the fixing bases 12 provided on the base plate 10, so that rigidity of the PCB 3 is enhanced. The fixing base 12 and the PCB 3 are coupled by a fixing screw 11 passing through the PCB 3. Each of the package terminals 2 of the semiconductor package 25 is inserted into a through hole (not illustrated) of the PCB 3, is physically and electrically connected to a circuit pattern (not illustrated) provided on a surface of the PCB 3, and has a tip projecting from a surface of the PCB 3.

On an upper surface of the PCB 3, a plurality of the upper surface main terminal electrodes 27 are arranged along two long sides of the PCB 3 at positions on the outer side than the press-fit terminals 5. Note that, a plurality of the upper surface main terminal electrodes 27 arranged along one long side and a plurality of the upper surface main terminal electrodes 27 arranged along another long side have different functions, but this fact is weakly related to the present disclosure and thus is omitted from description.

A plurality of the upper surface main terminal electrodes 27 provided on an upper surface of the PCB 3 can be freely laid out, and connection to a higher system of the semiconductor module 800 can be established without changing terminal arrangement of the semiconductor package 25 according to the higher system.

### <Variation>

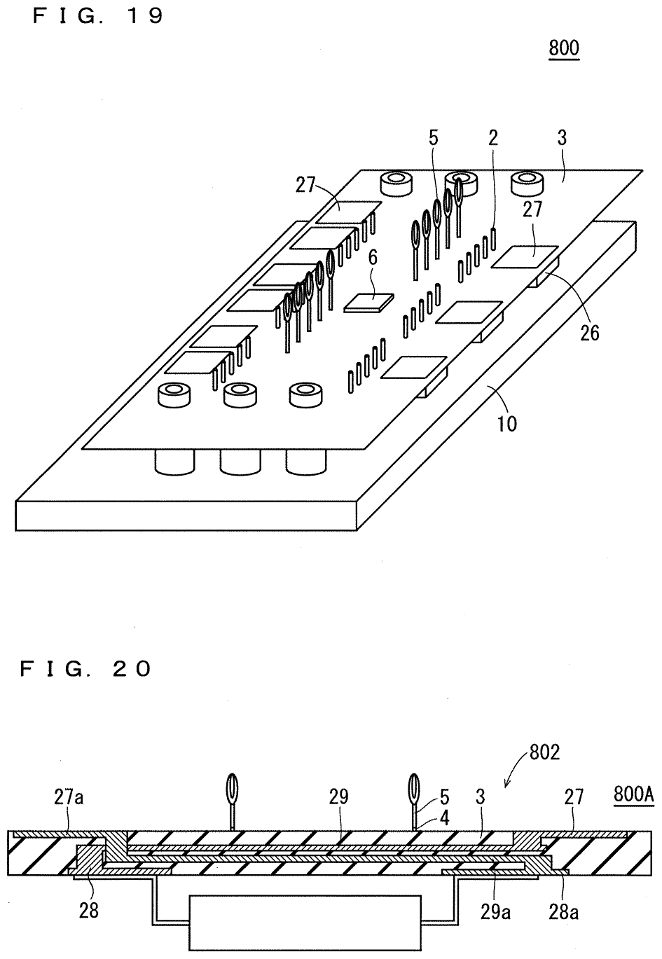

FIG. 20 is a side view illustrating a configuration of a semiconductor module 800A of a variation of the eighth preferred embodiment according to the present disclosure, and illustrates only the PCB 3 in a cross-sectional view. As illustrated in FIG. 20, in the semiconductor module 800A, a package assembly 802 includes the PCB 3, a plurality of the terminal blocks 4 mounted on the PCB 3, the press-fit terminal 5 connected to each of the terminal blocks 4, the upper surface main terminal electrodes 27 and 27a provided on an upper surface of the PCB 3, the lower surface main terminal electrodes 28 and 28a provided on a lower surface of the PCB 3, and the in-substrate wirings 29 and 29a. The upper surface main terminal electrode 27 and the lower surface main terminal electrode 28 are electrically connected to each other via the in-substrate wiring 29, and the upper surface main terminal electrode 27a and the lower surface main terminal electrode 28a are electrically connected to each other via the in-substrate wiring 29a. The upper surface main terminal electrode 27 and the lower surface main terminal electrode 28 are arranged on opposite sides with the semiconductor package 25 interposed between them, and the upper surface main terminal electrode 27a and the lower surface main terminal electrode 28a are arranged on opposite sides with the semiconductor package 25 interposed between them. For this reason, directions of current flowing through the in-substrate wirings 29 and 29a are opposite to each other. Note that, although FIG. 20 illustrates the configuration in which the main current terminals 26 project from two side surfaces of one of the semiconductor package 25, it is also possible to employ a configuration in which two of the semiconductor packages 25 are arranged and the main current terminals 26 project from one side surface in directions opposite to each other.

The main current terminal 26 projecting from one side surface of the semiconductor package 25 is physically and electrically connected to the lower surface main terminal electrode 28 by soldering or the like, and the main current terminal 26 projecting from another side surface of the semiconductor package 25 is physically and electrically connected to the lower surface main terminal electrode 28a by soldering or the like.

The in-substrate wirings 29 and 29a are stacked and arranged so as to be parallel flat plates in a substrate, and directions of current flowing through the wirings are opposite to each other, so that reduction in inductance and reduction in noise can be achieved.

Note that, in the present disclosure, within the scope of the disclosure, preferred embodiments can be freely combined with each other, and each preferred embodiment can be appropriately modified or omitted.

The present disclosure described above will be collectively described as Appendix.

### (Appendix 1)

A semiconductor module comprising a molded package in which a semiconductor chip is sealed with transfer molding resin, and a package assembly attached to a package terminal projecting from a package side surface of the molded package. The package assembly includes a printed circuit board that is physically and electrically connected to the package terminal, and an external terminal mounted on the printed circuit board and electrically connected to the package terminal.

### (Appendix 2)

The semiconductor module according to Appendix 1, in which the external terminal is mounted at a position closer to a center of the molded package than the package side surface.

### (Appendix 3)

The semiconductor module according to Appendix 1, in which the external terminal is mounted at a position farther from a center of the molded package than the package side surface.

### (Appendix 4)

The semiconductor module according to Appendix 1, in which the printed circuit board is bonded to a surface of the molded package.

### (Appendix 5)

The semiconductor module according to Appendix 1, in which an electronic component is mounted on the printed circuit board.

### (Appendix 6)

The semiconductor module according to Appendix 5, in which in the printed circuit board, the electronic component is mounted on both surfaces of a substrate.

### (Appendix 7)

The semiconductor module according to Appendix 1, in which the molded package is a plurality of molded packages, and the printed circuit board is physically and electrically connected to the package terminal of each of a plurality of the molded packages.

### (Appendix 8)

The semiconductor module according to Appendix 1, in which the molded package is a surface mount molded package.

### (Appendix 9)

The semiconductor module according to Appendix 8, in which in the printed circuit board, the surface mount molded package is mounted on both surfaces of a substrate.

### (Appendix 10)

The semiconductor module according to Appendix 8, in which in the surface mount molded package, the package terminal is sealed with resin.

### (Appendix 11)

The semiconductor module according to Appendix 8, in which the package assembly further includes a guide having a case shape that accommodates the surface mount molded package, and resin is sealed in the guide, and the surface mount molded package including the package terminal is sealed.

### (Appendix 12)

The semiconductor module according to Appendix 8, in which the printed circuit board further includes a first main terminal electrode provided on a first surface of the printed circuit board, the first main terminal electrode projecting from the package side surface of the surface mount molded package, the first main terminal electrode being physically and electrically connected to a main current terminal through which main current flows, a second main terminal electrode provided on a second surface opposite to the first surface of the printed circuit board, and an in-substrate wiring that is provided inside the printed circuit board and electrically connects the first main terminal electrode and the second main terminal electrode.

### (Appendix 13)

The semiconductor module according to Appendix 12, in which the in-substrate wiring is stacked and arranged so as to be a parallel flat plate with another in-substrate wiring inside the printed circuit board.

### (Appendix 14)

A semiconductor module comprising a molded package in which a semiconductor chip is sealed with transfer molding resin, and a package assembly attached to a package terminal projecting from a package side surface of the molded package, in which the molded package is a non-insulating semiconductor package in which a conductor member on which the semiconductor chip is mounted is exposed from a surface, and the package assembly includes an insulating substrate to which the conductor member of the non-insulating semiconductor package is physically and electrically connected, and an external terminal mounted on the insulating substrate and electrically connected to the package terminal.

### (Appendix 15)

A semiconductor module comprising a molded package in which a semiconductor chip is sealed with transfer molding resin, and a package assembly attached to a package terminal projecting from a package side surface of the molded package, in which the package assembly includes an insulating substrate to which a surface of the molded package is physically connected, and an external terminal mounted on the insulating substrate and electrically connected to the package terminal.

While the disclosure has been shown and described in detail, the foregoing description is in all aspects illustrative and not restrictive. It is therefore understood that numerous modifications and variations can be devised.

What is claimed is:

1. A semiconductor module comprising:
a molded package in which a semiconductor chip is sealed with transfer molding resin; and
a package assembly attached to a package terminal projecting from a package side surface of the molded package, wherein
the package assembly includes:
a printed circuit board that is physically and electrically connected to the package terminal; and
an external terminal mounted on the printed circuit board and electrically connected to the package terminal.

2. The semiconductor module according to claim 1, wherein
the external terminal is mounted at a position closer to a center of the molded package than the package side surface.

3. The semiconductor module according to claim 1, wherein
the external terminal is mounted at a position farther from a center of the molded package than the package side surface.

4. The semiconductor module according to claim 1, wherein
the printed circuit board is bonded to a surface of the molded package.

5. The semiconductor module according to claim 1, wherein
an electronic component is mounted on the printed circuit board.

6. The semiconductor module according to claim 5, wherein
in the printed circuit board, the electronic component is mounted on both surfaces of a substrate.

7. The semiconductor module according to claim 1, wherein
the molded package is a plurality of molded packages, and
the printed circuit board is physically and electrically connected to the package terminal of each of the plurality of molded packages.

8. The semiconductor module according to claim 1, wherein
the molded package is a surface mount molded package.

9. The semiconductor module according to claim 8, wherein
in the printed circuit board, the surface mount molded package is mounted on both surfaces of a substrate.

10. The semiconductor module according to claim 8, wherein
in the surface mount molded package, the package terminal is sealed with resin.

11. The semiconductor module according to claim 8, wherein
the package assembly further includes a guide having a case shape that accommodates the surface mount molded package, and
resin is sealed in the guide, and the surface mount molded package including the package terminal is sealed.

12. The semiconductor module according to claim 8, wherein
the printed circuit board further includes:
a first main terminal electrode provided on a first surface of the printed circuit board, the first main terminal electrode projecting from the package side surface of the surface mount molded package, the first main terminal electrode being physically and electrically connected to a main current terminal through which main current flows;
a second main terminal electrode provided on a second surface opposite to the first surface of the printed circuit board; and
an in-substrate wiring that is provided inside the printed circuit board and electrically connects the first main terminal electrode and the second main terminal electrode.

13. The semiconductor module according to claim 12, wherein
the in-substrate wiring is stacked and arranged so as to be a parallel flat plate with another in-substrate wiring inside the printed circuit board.

14. A semiconductor module comprising:
a molded package in which a semiconductor chip is sealed with transfer molding resin; and
a package assembly attached to a package terminal projecting from a package side surface of the molded package, wherein
the molded package is a non-insulating semiconductor package in which a conductor member on which the semiconductor chip is mounted is exposed from a surface, and
the package assembly includes:
an insulating substrate to which the conductor member of the non-insulating semiconductor package is physically and electrically connected; and
an external terminal mounted on the insulating substrate and electrically connected to the package terminal.

15. A semiconductor module comprising:
a molded package in which a semiconductor chip is sealed with transfer molding resin; and
a package assembly attached to a package terminal projecting from a package side surface of the molded package, wherein
the package assembly includes:
an insulating substrate to which a surface of the molded package is physically connected; and
an external terminal mounted on the insulating substrate and electrically connected to the package terminal.
